(19) United States
(12) Patent Application Publication
(10) Pub. No.: US 2026/0367299 A1
(43) Pub. Date: Nov. 19, 2026

(54) CURABLE COMPOSITION, CURED LAYER USING THE COMPOSITION AND DISPLAY DEVICE INCLUDING THE CURED LAYER

(71) Applicant: SAMSUNG SDI CO., LTD., Yongin-si (KR)

(72) Inventors: Yong Hee KANG, Suwon-si (KR); Chul Kyu KIM, Suwon-si (KR)

(21) Appl. No.: 19/630,107

(22) Filed: Mar. 26, 2026

(30) Foreign Application Priority Data
May 2, 2025 (KR) 10-2025-0058189

(51) Int. Cl. G02B 5/20; C09K 11/06; C09K 113/00; G02B 5/02; H10H 29/85; H10K 59/38

(52) U.S. Cl. CPC G02B 5/207; C09K 11/06; G02B 5/0242; H10H 29/8517; H10K 59/38; C09K 2113/00; C09K 2211/1088

(57) ABSTRACT

A curable composition, a cured layer formed from the curable composition; and a display device including the cured layer are disclosed. The curable composition includes: quantum dots containing a first ligand and a second ligand; and a polymerizable compound, where the first ligand is a compound containing a carboxyl group and a substituted or unsubstituted (meth)acrylate group, and the second ligand is a compound containing a thiol group and a substituted or unsubstituted C₆ to C₃₀ aryl group.

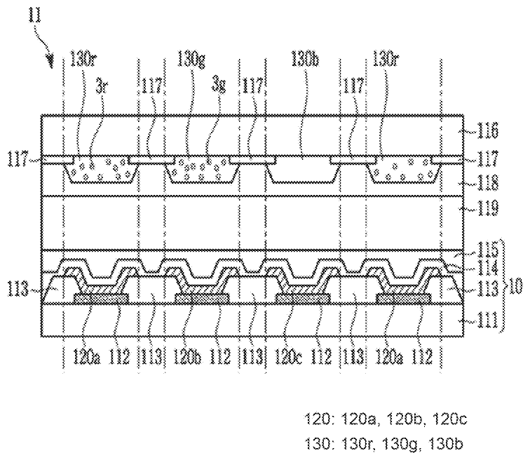

### CROSS-REFERENCE TO RELATED APPLICATION

The present application claims priority to and the benefit of Korean Patent Application No. 10-2025-0058189, filed on May 2, 2025, in the Korean Intellectual Property Office, the entire disclosure of which is incorporated herein by reference.

### BACKGROUND

### 1. Field

One or more embodiments of the present disclosure relate to (i) a curable composition, (ii) a cured layer formed of the composition, and (iii) a display device including the cured layer.

### 2. Description of the Related Art

Because typical quantum dots have hydrophobic surface properties, they can be dispersed only in a narrow range of solvents. As a result, it becomes highly challenging to introduce the typical quantum dots into a polar system, such as a binder or a curable monomer.

For example, even quantum dot ink compositions that have been actively studied in the art exhibit relatively low polarity and, in early research stages, could be dispersed only in highly hydrophobic solvents used for curable compositions. As a result, it was difficult for such compositions to contain 20 wt % or more of quantum dots based on the total weight of the composition. This limitation prevented the optical efficiency of the composition from improving beyond a certain level. Moreover, when additional quantum dots were forcibly added and dispersed to increase the optical efficiency, the viscosity of the composition would increase beyond a viscosity range suitable for ink-jetting, resulting in inadequate processability.

In the art, the solid content of ink compositions is often reduced by incorporating 50 wt % or more of a solvent to ensure a suitable viscosity range for ink-jetting, which provides somewhat satisfactory results in terms of viscosity. However, this approach introduces several drawbacks, such as nozzle drying caused by solvent volatilization during ink-jetting, nozzle clogging, progressive decrease in film thickness after ink-jetting, and severe thickness deviation after curing. These issues ultimately hinder their practical applications in manufacturing processes.

Accordingly, solvent-free curable compositions (quantum dot ink compositions that do not use solvents) have been developed in the art. However, incorporating excessive amounts of polymerizable compounds introduces several issues, including nozzle clogging and poor ejection caused by drying from volatilization, reductions in film thickness within patterned partition pixels due to volatilization of the jetted ink composition, and most critically, significant difficulty in enhancing optical properties.

Consequently, neither solvent-containing curable compositions nor solvent-free curable compositions have yet achieved a satisfactory level of light resistance reliability.

### SUMMARY

One or more aspects of embodiments of the present disclosure are directed toward a curable composition that has high stability of quantum dots to ensure good dispersibility of the quantum dots, thereby ensuring good optical properties and reliability, such as heat resistance and light resistance.

One or more aspects of embodiments the present disclosure are directed toward a cured layer formed of the curable composition.

One or more aspects of embodiments of the present disclosure are directed toward a display device including the cured layer.

Additional aspects will be set forth in part in the description which follows and, in part, will be apparent from the description, or may be learned by practice of the presented embodiments of the disclosure.

According to one or more embodiments of the present disclosure, a curable composition includes: quantum dots containing a first ligand and a second ligand; and

a polymerizable compound, wherein the first ligand is a compound containing a carboxyl group and a substituted or unsubstituted (meth)acrylate group, and the second ligand is a compound containing a thiol group and a substituted or unsubstituted C₆ to C₃₀ aryl group.

The first ligand may be a compound represented by Formula 1:

R¹-L¹-L²-R², Formula 1
where R¹ may be a carboxyl group;
L¹ and L² may be each independently a single bond, a substituted or unsubstituted C₁ to C₁₀ alkylene group, a substituted or unsubstituted C₂ to C₁₀ alkenylene group, a carbonyl group (—CO—), an ether group (—O—), an ester group (—COO—), or a combination thereof; and
R² may be a substituted or unsubstituted (meth)acrylate group or a group represented by Formula 2:

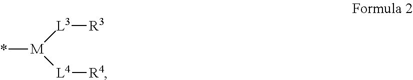

where M may be a substituted or unsubstituted C₃ to C₁₀ cycloalkylene group, a trivalent hydrocarbon group, or a combination thereof;
L³ and L⁴ may be each independently a single bond, a substituted or unsubstituted C₁ to C₁₀ alkylene group, an ester group, or a combination thereof; and
R³ and R⁴ may be each independently a substituted or unsubstituted (meth)acrylate group or a substituted or unsubstituted allyloxy group, provided that at least one of R³ or R⁴ is a substituted or unsubstituted (meth)acrylate group.

In one or more embodiments, L¹ and L² may be each independently a single bond, a substituted or unsubstituted C₁ to C₁₀ alkylene group, or a combination thereof, and R² may be a substituted or unsubstituted (meth)acrylate group.

In one or more embodiments, L¹ and L² may be each independently a substituted or unsubstituted C₁ to C₁₀ alkylene group, a substituted or unsubstituted C₂ to C₁₀ alkenylene group, or an ester group (—COO—), and M may be a trivalent hydrocarbon group.

In one or more embodiments, L¹ and L² may be each a single bond, and M may be a C₄ to C₁₀ cycloalkylene group substituted with a carboxyl group.

In one or more embodiments, the first ligand may be a compound represented by any one selected from among Formulas 1-1 to 1-3:

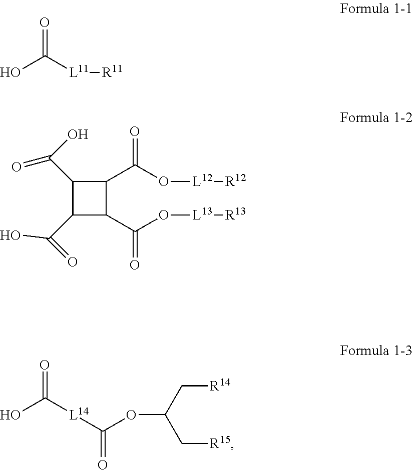

where L¹¹ to L¹⁴ may be each independently a substituted or unsubstituted C₁ to C₁₀ alkylene group, a substituted or unsubstituted C₂ to C₁₀ alkenylene group, or a substituted or unsubstituted C₂ to C₁₀ alkyl ether group;
R¹¹ may be a substituted or unsubstituted (meth)acrylate group; and
R¹² to R¹⁵ may be each independently a substituted or unsubstituted (meth)acrylate group or a substituted or unsubstituted allyloxy group, provided that at least one of R¹² or R¹³ and at least or of R¹⁴ and R¹⁵ are each a substituted or unsubstituted (meth)acrylate group.

In one or more embodiments, the second ligand may be a compound represented by Formula 3:

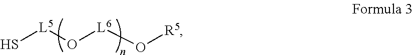

where R⁵ may be a substituted or unsubstituted C₆ to C₂₀ aryl group;
L⁵ and L⁶ may be each independently a substituted or unsubstituted C₁ to C₁₀ alkylene group; and
n may be an integer of 0 to 10.

In one or more embodiments, R⁵ may be a substituted or unsubstituted benzene group.

In one or more embodiments, the curable composition may be a solvent-free curable composition.

The solvent-free curable composition may include about 5 wt % to about 60 wt % of the quantum dots; and about 40 wt % to about 95 wt % of the polymerizable compound based on the total weight of 100 wt % of the solvent-free curable composition.

In one or more embodiments, the curable composition may further include a polymerization initiator, a light diffusing agent, a polymerization inhibitor, or a combination thereof.

The light diffusing agent may include barium sulfate, calcium carbonate, titanium dioxide, zirconia, or a combination thereof.

The quantum dots may include a cadmium-free luminescent material.

In one or more embodiments, the quantum dots may have a core/shell structure of InP/ZnS or a core/first shell/second shell structure of InP/ZnSe/ZnS.

In one or more embodiments, the quantum dots may include: a core including Ag, In, Ga, and S; and a shell including at least two selected from the group consisting of Ag, Ga, Zn, and S.

In one or more embodiments, the curable composition may further include: malonic acid; 3-amino-1,2-propanediol; a silane-based coupling agent; a leveling agent; a fluorinated surfactant; or a combination thereof.

In one or more embodiments, the curable composition may further include a solvent.

The curable composition may include about 1 wt % to about 40 wt % of the quantum dots; about 1 wt % to about 20 wt % of the polymerizable compound; and about 40 wt % to about 80 wt % of the solvent, based on the total weight of 100 wt % of the curable composition.

According to one or more embodiments of the present disclosure, there is provided a cured layer produced from the curable composition.

According to one or more embodiments of the present disclosure, a display device includes the curable film.

Details of one or more aspects of the present disclosure will be described in the following detailed description.

One or more embodiments of the present disclosure provide quantum dot-containing curable compositions that include quantum dots subjected to surface modification with surface modifiers of one or more embodiments, thereby improving reliability and optical properties.

### BRIEF DESCRIPTION OF THE DRAWING

The accompanying drawing is included to provide a further understanding of the present disclosure and is incorporated in and constitutes a part of the present disclosure. The drawing illustrates embodiments of the present disclosure and, together with the description, serves to explain principles of the present disclosure. The above and other aspects, features, and benefits of the present disclosure will become more apparent to those of ordinary skill in the art from the following exemplary embodiments thereof described in detail with reference to the accompanying drawing, in which:

The drawing illustrates a schematic cross-sectional view of a display device according to one or more embodiments of the present disclosure.

### DETAILED DESCRIPTION

Hereinafter, one or more embodiments of the present disclosure will be described in detail with reference to the accompanying drawing. It should be understood that the following embodiments are provided for illustration and explanation, and the present disclosure is not limited thereto and is defined by the appended claims and equivalents thereof.

Herein, unless stated otherwise, the term “alkyl group” refers to a C₁ to C₂₀ alkyl group, the term “alkenyl group” refers to a C₂ to C₂₀ alkenyl group, the term “cycloalkyl group” refers to a C₃ to C₂₀ cycloalkyl group, the term “cycloalkenyl group” refers to a C₃ to C₂₀ cycloalkenyl group, the term “heterocycloalkyl group” refers to a C₂ to C₂₀ heterocycloalkyl group, the term “heterocycloalkenyl group” refers to a C₂ to C₂₀ heterocycloalkenyl group, the term “aryl group” refers to a C to C₂₀ aryl group, the term “arylalkyl group” refers to a C₇ to C₂₀ arylalkyl group, the term “alkylene group” refers to a C₁ to C₂₀ alkylene group, the term “arylene group” refers to a C₆ to C₂₀ arylene group, the term “alkylarylene group” refers to a C₇ to C₂₀ alkylarylene group, the term “heteroarylene group” refers to a C₃ to C₂₀ heteroarylene group, and term “alkoxylene group” refers to a C₁ to C₂₀ alkoxylene group.

Herein, unless stated otherwise, “substituted” may refer to that at least one hydrogen atom of a functional group is substituted with a halogen (for example, F, Cl, Br, or I), a hydroxyl group, a C₁ to C₂₀ alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid group or a salt thereof, a C₁ to C₂₀ alkyl group, a C₂ to C₂₀ alkenyl group, a C₂ to C₂₀ alkynyl group, a C₆ to C₂₀ aryl group, a C₃ to C₂₀ cycloalkyl group, a C₃ to C₂₀ cycloalkenyl group, a C₃ to C₂₀ cycloalkynyl group, a C₂ to C₂₀ heterocycloalkyl group, a C₂ to C₂₀ heterocycloalkenyl group, a C₂ to C₂₀ heterocycloalkynyl group, a C₃ to C₂₀ heteroaryl group, or a combination thereof.

Herein, unless stated otherwise, the term “hetero” may refer to that the corresponding formula includes at least one hetero atom selected from among N, O, S, and P.

Herein, unless stated otherwise, the term “(meth)acrylate” refers to “acrylate” and/or “methacrylate”, and the term “(meth)acrylic acid” refers to “acrylic acid” and/or “methacrylic acid”.

Herein, unless stated otherwise, the term “combination” refers to mixing or copolymerization.

In chemical formulas herein, unless defined otherwise, the absence of a chemical bond at a position where a chemical bond should be drawn indicates that a hydrogen atom is bonded at that position.

In addition, unless stated otherwise herein, “*” indicates a link to the same or different atoms or chemical formulas.

A quantum dot-containing curable composition according to one or more embodiments of the present disclosure may exhibit superior or suitable heat/light resistance properties through surface modification of the quantum dots using surface modifiers with designed structures, as compared to general quantum dot-containing curable compositions.

As a light source is being replaced from organic light-emitting diodes (OLEDs) to micro-LEDs in the display field, light resistance of a film arranged inside a display device is becoming more critical than ever. Therefore, it has become very important to improve light resistance of a cured layer produced by curing a quantum dot-containing curable composition. However, general quantum dot surface modifiers alone are not sufficient to achieve good film light resistance suitable for use with micro-LED light sources.

Generally, a high sensitivity initiator or a polyfunctional monomer is additionally used to improve the curing rate of a quantum dot-containing curable composition, and in all of such conventional techniques, although one of properties of the quantum dot-containing curable composition, such as dispersibility, heat resistance, and curing rate, can be improved by selecting a specific composition, there is a trade-off issue in that other properties other than the properties improved by the selected composition become inferior. In other words, currently, there is no established technology for quantum dot-containing curable compositions that achieve high light resistance properties while maintaining low viscosity.

For example, state-of-the-art techniques include modification of the quantum dot surface with polymers or siloxane-based organic materials (for example, tetraethyl orthosilicate (TEOS)) containing heat-resistant functional groups, or encapsulation of the quantum dot surface with one or more inorganic materials, such as aluminum, titanium, or oxides thereof. In recent years, it has also been attempted to increase both brightness and durability by doping small amounts of transition metals (Cu, Mg, and/or the like) during synthesis of quantum dots.

However, all of these methods remain at the level of academic research not yet applicable to practical display applications. In general, displays adopting quantum dots aim to improve brightness by increasing light intensity. However, improved brightness through increased light intensity compromises stability of the quantum dots, thereby leading to inevitable challenges in improving panel reliability.

Therefore, the inventors continued their research and developed a curable composition that ensures good heat and light resistance through improvement in dispersion of the quantum dots.

Specifically, a curable composition according to one or more embodiments may include: quantum dots containing a first ligand and a second ligand; and a polymerizable compound, wherein the first ligand is a compound containing a carboxyl group and a substituted or unsubstituted (meth)acrylate group, and the second ligand is a compound containing a thiol group and a substituted or unsubstituted C₆ to C₃₀ aryl group.

Hereinafter, each of the components constituting the curable composition according to one or more embodiments will be described in detail.

### Quantum Dots

The most efficient ligand structure currently available for passivation of the quantum dot surface with organic ligands is a ligand having a thiol group, as is well known in the art, a carboxylic acid-type ligand exhibits relatively weak binding affinity to the quantum dot surface, and a phosphoric acid-type ligand degrades efficiency (causing color change) notwithstanding its good dispersion of the quantum dots.

As current display techniques have been progressed, starting from liquid crystal displays (LCDs) to OLEDs, near-eye displays (NEDs), and state-of-the-art micro-LEDs, there is a need for substantially improving the durability (especially heat and light resistance) of the quantum dots corresponding to increase in intensity of blue light.

Therefore, one or more embodiments of the present disclosure employ two types of ligands with different structures for effective passivation of the quantum dot surface.

First, the first ligand according to one or more embodiments of the present disclosure will be described.

As described above, the first ligand is a compound containing a carboxyl group and a substituted or unsubstituted (meth)acrylate group.

In one or more embodiments, the first ligand may contain a carboxyl group and a substituted or unsubstituted acrylate group, in one or more embodiments, the first ligand may contain a carboxyl group and a substituted or unsubstituted methacrylate group, and in one or more embodiments, the first ligand may contain a carboxyl group, a substituted or unsubstituted acrylate group, and a substituted or unsubstituted methacrylate group.

For example, in one or more embodiments, the first ligand may be a compound represented by Formula 1:

R¹-L¹-L²-R², Formula 1
where R¹ may be a carboxyl group;
L¹ and L² may be each independently a single bond, a substituted or unsubstituted C₁ to C₁₀ alkylene group, a substituted or unsubstituted C₂ to C₁₀ alkenylene group, a carbonyl group (—CO—), an ether group (—O—), an ester group (—COO—), or a combination thereof; and
R² may be a substituted or unsubstituted (meth)acrylate group or a group represented by Formula 2:

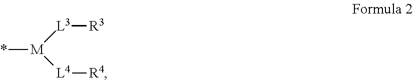

where M may be a substituted or unsubstituted C₃ to C₁₀ cycloalkylene group, a trivalent hydrocarbon group, or a combination thereof;
L³ and L⁴ may be each independently a single bond, a substituted or unsubstituted C₁ to C₁₀ alkylene group, an ester group, or a combination thereof; and
R³ and R⁴ may be each independently a substituted or unsubstituted (meth)acrylate group or a substituted or unsubstituted allyloxy group, provided that at least one of R³ or R⁴ is a substituted or unsubstituted (meth)acrylate group.

As used herein, the term “allyloxy group” refers to a monovalent organic group including (e.g., consisting of) an allyl group (CH₂═CH—CH₂—*) and an oxygen (O), and may be represented by CH₂═CH—CH₂—O—*.

By introducing the first ligand containing a carboxyl group and a substituted or unsubstituted (meth)acrylate group at respective ends, and the second ligand described below, the quantum dots according to one or more embodiments of the present disclosure may achieve both high quantum efficiency and reliability at the same time.

For example, in one or more embodiments, in Formula 1, L¹ and L² may be each independently a single bond, a substituted or unsubstituted C₁ to C₁₀ alkylene group, or a combination thereof, and R² may be a substituted or unsubstituted (meth)acrylate group, without being limited thereto.

For example, in one or more embodiments, in Formula 1, L¹ and L² may be each independently a substituted or unsubstituted C₁ to C₁₀ alkylene group, a substituted or unsubstituted C₂ to C₁₀ alkenylene group, or an ester group (—COO—), and in Formula 2, M may be a trivalent hydrocarbon group, without being limited thereto. In one or more embodiments, the trivalent hydrocarbon group may have a structure in which three functional groups are bonded to a centrally located carbon atom.

For example, in one or more embodiments, in Formula 1, L¹ and L² are each a single bond, and in Formula 2, M may be a substituted or unsubstituted C₃ to C₁₀ cycloalkylene group. For example, M may be a C₄ to C₁₀ cycloalkylene group substituted with a carboxyl group, without being limited thereto. In one or more embodiments, in Formula 1, L¹ and L² are each a single bond; and in Formula 2, M is a substituted C₄ to C₁₀ cycloalkylene group, and L³ and L⁴ may be any combination of C₁ to C₁₀ alkylene groups substituted or unsubstituted with an ester group, without being limited thereto.

For example, in one or more embodiments, the first ligand may be a compound represented by any one selected from among Formulas 1-1 to 1-3, without being limited thereto.

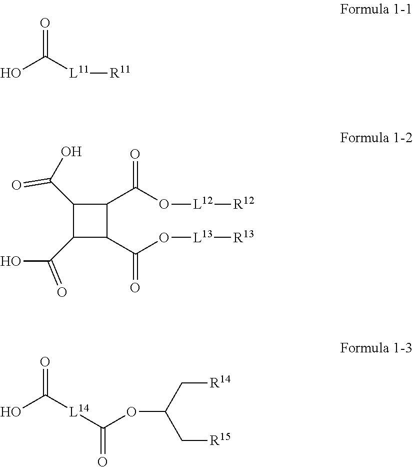

where L¹¹ to L¹⁴ may be each independently a substituted or unsubstituted C₁ to C₁₀ alkylene group, a substituted or unsubstituted C₂ to C₁₀ alkenylene group, or a substituted or unsubstituted C₂ to C₁₀ alkyl ether group;
R¹¹ may be a substituted or unsubstituted (meth)acrylate group; and
R¹² to R¹⁵ may be each independently a substituted or unsubstituted (meth)acrylate group or a substituted or unsubstituted allyloxy group, provided that at least one of R¹² or R¹³ and at least one of R¹⁴ or R¹⁵ are each a substituted or unsubstituted (meth)acrylate group.

As used herein, the term “alkyl ether group” refers to a bivalent organic group in which two alkylene groups are connected to each other by an oxygen atom, and may be represented by *—(CH₂)ₙ—O—(CH₂)ₘ—* (where n and m are each an integer).

Next, the second ligand according to one or more embodiments of the present disclosure will be described.

The second ligand contains a thiol group and a substituted or unsubstituted C₆ to C₃₀ aryl group therein.

For example, in one or more embodiments, the second ligand may be a compound represented by Formula 3:

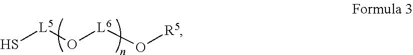

where R⁵ may be a substituted or unsubstituted C₆ to C₂₀ aryl group;
L⁵ and L⁶ may be each independently a substituted or unsubstituted C₁ to C₁₀ alkylene group; and
n is an integer of 0 to 10.

In one or more embodiments, in Formula 3, R⁵ may be, for example, a substituted or unsubstituted benzene group or a substituted or unsubstituted naphthalene group. In one or more embodiments, R⁵ may be a substituted or unsubstituted benzene group, without being limited thereto.

In one or more embodiments, in Formula 3, n may be, for example, 0, 1, 2, or 3, without being limited thereto, and the number of chains of the alkylene-oxy group may be adjusted in consideration of reactivity of the quantum dots.

By adopting the first ligand and the second ligand having different structures at the same time, the quantum dots according to one or more embodiments have good heat/light resistance reliability, whereby the quantum dot-containing curable composition subjected to surface modification with the two types of ligands may maintain initial light efficiency even when cured and mounted on a display panel in a single film state and exposed to strong blue light, such as micro-LEDs, for a long time.

When the quantum dots subjected to surface modification with the surface modifiers are added to the polymerizable compound described below and stirred, it may suitably obtain a very transparent dispersion, which becomes a measure to confirm that surface modification of the quantum dots is excellent and suitable.

For example, in one or more embodiments, the first ligand is present in an amount of about 20 wt % to about 80 wt % and the second ligand is present in an amount of about 80 wt % to about 10 wt %, based on the total weight of 100 wt % of the first ligand and the second ligand, without being limited thereto.

In one or more embodiments, the quantum dots may have a maximum fluorescence emission wavelength (e.g., fluorescence emission peak wavelength) of about 500 nm to about 680 nm.

For example, If (e.g., when) the curable composition according to one or more embodiments is a solvent-free curable composition, the quantum dots may be present in an amount of about 5 wt % to about 60 wt %, for example, about 10 wt % to about 60 wt %, for example, about 20 wt % to about 60 wt %, for example, about 30 wt % to about 50 wt %, based on the total amount (e.g., total weight) of 100 wt % of the curable composition. Within these amount ranges of the quantum dots, the curable composition may achieve high light retention and luminous efficacy even after curing. In the present disclosure, the term “solvent-free” refers to that a solvent is not added, selected, or utilized as a component in the composition, but the “solvent” of less than a suitable amount may still be present due to other impurities and/or external factors.

For example, if (e.g., when) the curable composition according to one or more embodiments is a solvent-containing curable composition, the quantum dots may be present in an amount of about 1 wt % to about 40 wt %, for example, about 3 wt % to about 30 wt %, based on the total weight of 100 wt % of the curable composition. Within these amount ranges of the quantum dots, the curable composition may secure good photoconversion and good processability without impairing pattern characteristics and development characteristics.

As described herein, quantum dot-containing curable compositions (inks) have been developed and even commercialized by specializing thiol-based binders or monomers having good compatibility with quantum dots.

For example, in one or more embodiments, the quantum dots may absorb light in the wavelength range of about 360 nm to about 780 nm, for example, about 400 nm to about 780 nm, and emit fluorescence in the wavelength range of about 500 nm to about 700 nm, for example, about 500 nm to about 580 nm, or in the wavelength range of about 600 nm to about 680 nm. In other words, the quantum dots may have a maximum fluorescence emission wavelength (e.g., fluorescence emission peak wavelength)(fluorescence λₑₘ) in the wavelength range of about 500 nm to about 680 nm.

The quantum dots may each independently have a full width at half maximum (FWHM) of about 20 nm to about 100 nm, for example, about 20 nm to about 50 nm. With the full width at half maximum within this range, the quantum dots may have high color purity, thereby improving color reproduction when used as a light conversion material in a color filter.

Each of the quantum dots may be independently an organic material, an inorganic material, or a hybrid of organic and inorganic materials.

In one or more embodiments, the quantum dots may each independently include a core and a shell surrounding the core, in which the core and the shell may each independently have a structure, such as a core, a core/shell, a core/first shell/second shell, an alloy, an alloy/shell, and/or the like, composed of Group II-IV elements, Group III-V elements, and/or the like, without being limited thereto.

For example, in one or more embodiments, the core may include at least one material selected from the group consisting of CdS, CdSe, CdTe, ZnS, ZnSe, ZnTe, HgS, HgSe, HgTe, GaN, GaP, GaAs, InP, InAs, combinations thereof, and alloys thereof, without being limited thereto. The shell surrounding the core may include at least one material selected from the group consisting of CdSe, ZnSe, ZnS, ZnTe, CdTe, PbS, TiO₂, SrSe, HgSe, combinations thereof, and alloys thereof, without being limited thereto.

In one or more embodiments, driven by rising environmental concerns and strict global regulations on toxic substances, cadmium-free luminescent materials, such as InP/ZnS and InP/ZnSe/ZnS, which are more environmentally friendly despite a somewhat lower quantum yield, have been used instead of luminescent materials containing cadmium in a core. However, it should be understood that other implementations are possible.

In one or more embodiments, the quantum dots may include: a core including Ag, In, Ga, and S; and a shell including at least two (or at least three) selected from the group consisting of Ag, Ga, Zn, and S.

For the quantum dots with the above core/shell structure, each of the quantum dots including the shell may have a particle size (average particle diameter) of about 1 nm to about 15 nm, for example, about 5 nm to about 15 nm. In the present disclosure, when quantum dots or quantum dot particles are spherical, “diameter” or “size” indicates a particle diameter or an average particle diameter, and when the particles are non-spherical, the “diameter” or “size” indicates a major axis length or an average major axis length. The diameter/size of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

For example, the quantum dots may each independently include red quantum dots (e.g., quantum dots emitting red color light), green quantum dots (e.g., quantum dots emitting green color light), or a combination thereof. The red quantum dots may each independently have an average particle diameter of about 10 nm to about 15 nm. The green quantum dots may each independently have an average particle diameter of about 5 nm to about 8 nm.

For dispersion stability of the quantum dots, the curable composition according to one or more embodiments may further include a dispersant. The dispersant assists in uniform dispersion of a photoconversion material, such as quantum dots, within the curable composition, and may be a non-ionic dispersant, an anionic dispersant, or a cationic dispersant. For example, examples of the dispersant may include polyalkylene glycol or esters thereof, polyoxyalkylene, polyhydric alcohol ester alkylene oxide adducts, alcohol alkylene oxide adducts, sulfonic acid esters, sulfonic acid salts, carboxylic acid esters, carboxylic acid salts, alkyl amide alkylene oxide adducts, alkyl amine, and/or the like. These may be used alone or as a mixture thereof. In one or more embodiments, the dispersant may be present in an amount of about 0.1 wt % to 100 wt %, for example, about 10 wt % to about 20 wt %, relative to the solid content (e.g., solid weight) of the photoconversion material, such as quantum dots.

### Polymerizable Compound

The curable composition according to one or more embodiments includes the polymerizable compound. The polymerizable compound may have a terminal carbon-carbon double bond.

In one or more embodiments, the polymerizable compound having a terminal carbon-carbon double bond may be present in an amount of about 40 wt % to about 95 wt %, for example, about 50 wt % to about 90 wt %, based on the total weight of 100 wt % of the solvent-free curable composition. Within this range, the solvent-free curable composition may have a viscosity that allows ink jetting, and the quantum dots in the solvent-free curable composition may have good dispersibility to ensure improved optical properties.

For example, in one or more embodiments, the polymerizable compound having a terminal carbon-carbon double bond may have a molecular weight of about 170 g/mol to about 1,000 g/mol. Within this range, it is advantageous for ink-jetting because the polymerizable compound does not increase the viscosity of the curable composition while maintaining the optical properties of the quantum dots.

In one or more embodiments, the polymerizable compound having a terminal carbon-carbon double bond may include a compound represented by Formula 4, without being limited thereto:

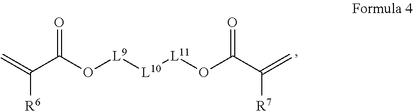

where R⁶ and R⁷ may be each independently hydrogen or a substituted or unsubstituted C₁ to C₁₀ alkyl group;
L⁹ and L¹¹ may be each independently a single bond or a substituted or unsubstituted C₁ to C₁₀ alkylene group; and
L¹⁰ may be a substituted or unsubstituted C₁ to C₁₀ alkylene group, a substituted or unsubstituted C₃ to C₂₀ cycloalkylene group, or an ether group (*—O—*).

In one or more embodiments, the polymerizable compound having a terminal carbon-carbon double bond may include a compound represented by Formula 4-1, Formula 4-2, or Formula 4-3, without being limited thereto.

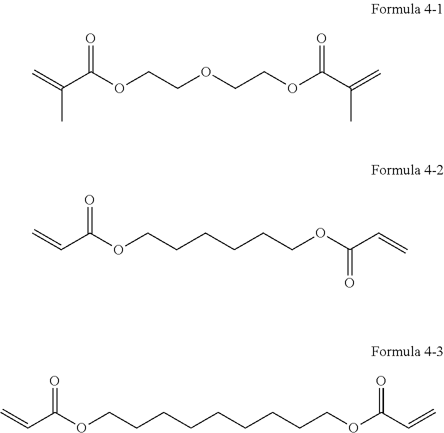

In one or more embodiments, in addition to the compound represented by Formula 4-1, Formula 4-2, or Formula 4-3, the polymerizable compound having a terminal carbon-carbon double bond may further include ethylene glycol diacrylate, triethylene glycol diacrylate, 1,4-butanediol diacrylate, neopentyl glycol diacrylate, pentaerythritol diacrylate, pentaerythritol triacrylate, dipentaerythritol diacrylate, dipentaerythritol triacrylate, dipentaerythritol pentaacrylate, pentaerythritol hexaacrylate, bisphenol A diacrylate, trimethylolpropanetriacrylate, novolac epoxyacrylate, ethylene glycol dimethacrylate, triethylene glycol dimethacrylate, propylene glycol dimethacrylate, 1,4-butanediol dimethacrylate, 1,6-hexanediol dimethacrylate, or a combination thereof.

In one or more embodiments, in addition to the polymerizable compound having a terminal carbon-carbon double bond, the curable compound may further include a monomer commonly used in a typical thermosetting or photocurable composition. For example, the monomer may further include an oxetane-based compound, such as bis[1-ethyl(3-oxetanyl)]methyl ether and/or the like.

In one or more embodiments, if (e.g., when) the curable composition includes a solvent, the polymerizable compound may be present in an amount of about 1 wt % to about 20 wt %, for example, about 1 wt % to about 15 wt %, for example, about 5 wt % to about 15 wt %, based on the total weight of 100 wt % of the curable composition. Within this range, the curable composition may secure improved optical properties of the quantum dots, good and suitable reliability through sufficient curing upon exposure in a pattern formation process, and good and suitable properties in terms of heat resistance, light resistance, chemical resistance, resolution, and adhesion of the pattern.

If (e.g., when) the curable composition includes a solvent, the polymerizable compound may include a monofunctional or polyfunctional ester of (meth)acrylic acid having at least one ethylenically unsaturated double bond.

With the ethylenically unsaturated double bonds, the polymerizable compound may form a pattern having good or suitable heat resistance, light resistance, and chemical resistance through sufficient polymerization upon exposure in a patterning process.

The polymerizable compound used in the solvent-containing curable composition may include, for example, ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy (meth)acrylate, ethylene glycol monomethyl ether(meth)acrylate, trimethylol propane tri(meth)acrylate, tris(meth)acryloyloxyethyl phosphate, novolac epoxy (meth)acrylate, and/or the like.

Non-limiting examples of commercially available products of the polymerizable compounds are as follows. Non-limiting examples of the monofunctional esters of the (meth)acrylic acid may include ARONIX M-101®, M-111®, M-114®, and/or the like from Toa Kosei Kagaku Kogyo Co., Ltd.; KAYARAD TC-110S®, TC-120S®, and/or the like from Nihon Kayaku Co., Ltd., and/or the like. Non-limiting examples of the bifunctional esters of the (meth)acrylic acid may include ARONIX M-210®, M-240®, M-6200®, and/or the like from Toa Kosei Kagaku Kogyo Co. Ltd.; KAYARAD HDDA®, HX-220®, R-604®, and/or the like from Nihon Kayaku Co. Ltd.; V-260®, V-312®, V-335 HP®, and/or the like from Osaka Yuki-Kagaku Kogyo Co., Ltd., and/or the like. Non-limiting examples of the trifunctional esters of the (meth)acrylic acid may include Aronix M-309®, M-400®, M-405®, M-450®, M-7100®, M-8030®, M-8060®, and/or the like from Toa Kosei Kagaku Kogyo Co., Ltd.; KAYARAD TMPTA®, DPCA-20®, DPCA-30®, DPCA-60®, DPCA-120®, and/or the like from Nihon Kayaku Co., Ltd.; V-295®, V-300®, V-360®, V-GPT®, V-3PAR, V-400®, and/or the like from Osaka Yuki-Kayaku Kogyo Co., Ltd., and/or the like. These products may be used alone or in combination thereof.

In one or more embodiments, the polymerizable compound may also be treated with an acid anhydride to impart better developability.

### Light Diffusing Agent

The curable composition according to one or more embodiments may further include a light diffusing agent.

For example, the light diffusing agent may include barium sulfate (BaSO₄), calcium carbonate (CaCO₃), titanium dioxide (TiO₂), zirconia (ZrO₂), or a combination thereof.

The light diffusing agent may reflect light not absorbed by the aforementioned quantum dots and allows the reflected light to be reabsorbed by the quantum dots. In other words, the light diffusing agent may increase photoconversion efficiency of the curable composition by increasing the amount of light absorbed by the quantum dots.

The light diffusing agent may have an average particle diameter (D₅₀) of about 150 nm to about 250 nm, for example about 180 nm to about 230 nm. Within this range, the light diffusing agent may secure better light diffusion while increasing light conversion efficiency.

The light diffusing agent may be present in an amount of about 1 wt % to about 20 wt %, for example, about 2 wt % to about 15 wt %, for example, about 2 wt % to about 10 wt %, based on the total weight of 100 wt % of the curable composition. If the content (e.g., amount) of the light diffusing agent is less than 1 wt % based on the total weight of the curable composition, it is difficult for the light diffusing agent to improve the photoconversion efficiency, and if the content (e.g., amount) of the light diffusing agent exceed 20 wt %, sedimentation of the quantum dots may occur.

### Polymerization Initiator

The curable composition according to one or more embodiments may further include a polymerization initiator. The polymerization initiator may include a photopolymerization initiator, a thermal polymerization initiator, or a combination thereof.

The photopolymerization initiator may be an initiator commonly used in photosensitive resin compositions, and may include an acetophenone-based compound, a benzophenone-based compound, a thioxanthone-based compound, a benzoin-based compound, a triazine-based compound, an oxime-based compound, and/or an aminoketone compound, without being limited thereto.

The acetophenone-based compound may include, for example, 2,2′-diethoxy acetophenone, 2,2′-dibutoxy acetophenone, 2-hydroxy-2-methylpropiophenone, p-t-butyl trichloroacetophenone, p-t-butyl dichloroacetophenone, 4-chloroacetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and/or the like.

The benzophenone-based compound may include, for example, benzophenone, benzoyl benzoate, methyl benzoyl benzoate, 4-phenyl benzophenone, hydroxybenzophenone, acrylated benzophenone, 4,4′-bis(dimethylamino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and/or the like.

The thioxanthone-based compound may include, for example, thioxanthone, 2-methylthioxanthone, isopropyl thioxanthone, 2,4-diethyl thioxanthone, 2,4-diisopropyl thioxanthone, 2,4-diisopropyl thioxanthone, 2-chlorothioxanthone, and/or the like.

The benzoin-based compound may include, for example, benzoin, benzoin methyl ether, benzoin ethyl ether, benzoin isopropyl ether, benzoin isobutyl ether, benzyl dimethyl ketal, and/or the like.

The triazine-based compound may include, for example, 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloromethyl)-s-triazine, bis(trichloromethyl)-6-styryl-s-triazine, 2-(naphthalen-1-yl)-4,6-bis(trichloromethyl)-s-triazine, 2-(4-methoxynaphthalen-1-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and/or the like.

The oxime-based compound may include, for example, O-acyloxime-based compounds, 2-(O-benzoyloxime)-1-[4-(phenylthio)phenyl]-1,2-octanedione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, and/or the like. For example, the O-acyloxime-based compounds may include, for example, 1,2-octanedione, 2-dimethylamino-2-(4-methylbenzyl)-1-(4-morpholin-4-yl-phenyl)-butane-1-one, 1-(4-phenylsulfonylphenyl)-butane-1,2-dione-2-oxime-O-benzoate, 1-(4-phenylsulfonylphenyl)-octane-1,2-dione-2-oxime-O-benzoate, 1-(4-phenylsulfonylphenyl)-octane-1-onoxime-O-acetate, 1-(4-phenylsulfonylphenyl)-butane-1-onoxime-O-acetate, and/or the like.

The aminoketone-based compound may include, for example, 2-benzyl-2-dimethylamino-1-(4-morpholinophenyl)-butanone-1 and the like.

In addition to the above compounds, a carbazole compound, a diketone compound, a sulfonium borate compound, a diazo compound, an imidazole compound, a bi-imidazole compound, and/or the like may also be used as the photopolymerization initiator.

In one or more embodiments, the photopolymerization initiator may also be used together with a photosensitizer, which absorbs light to reach an excited state and transfers energy to induce a chemical reaction.

The photosensitizer may include, for example, tetraethylene glycol bis-3-mercaptopropionate, pentaerythritol tetrakis-3-mercaptopropionate, dipentaerythritol tetrakis-3-mercaptopropionate, and/or the like.

The thermal polymerization initiator may include, for example, one or more selected from among peroxides, for example, benzoyl peroxide, dibenzoyl peroxide, lauryl peroxide, dilauryl peroxide, di-tert-butyl peroxide, cyclohexane peroxide, methyl ethyl ketone peroxide, hydroperoxides (for example, tert-butyl hydroperoxide, cumene hydroperoxide, and the like), dicyclohexyl peroxydicarbonate, 2,2-azo-bis(isobutyronitrile), t-butyl perbenzoate, 2,2′-azobis-2-methylpropionitrile, and the like, without being limited thereto. However, it should be understood that any thermal polymerization initiator suitable in the art may also be used.

The polymerization initiator may be present in an amount of about 0.1 wt % to about 10 wt %, for example, about 2 wt % to about 8 wt %, based on the total weight of 100 wt % of the curable composition. Within this range, the polymerization initiator may ensure sufficient photo or thermal curing to achieve high reliability while preventing transmittance loss caused by unreacted initiator, thereby maintaining the optical properties of the quantum dots.

### Binder Resin

The curable composition according to one or more embodiments may further include a binder resin.

The binder resin may include an acrylic-based resin, a cardo-based resin, an epoxy-based resin, or a combination thereof.

The acrylic-based resin may be a copolymer of a first ethylenically unsaturated monomer and a second ethylenically unsaturated monomer copolymerizable therewith, and may include at least one acrylic repeat unit.

For example, the acrylic-based binder resin may include, for example, poly(benzyl methacrylate), a (meth)acrylic acid/benzyl methacrylate copolymer, a (meth)acrylic acid/benzyl methacrylate/styrene copolymer, a (meth)acrylic acid/benzyl methacrylate/2-hydroxyethyl methacrylate copolymer, and a (meth)acrylic acid/benzyl methacrylate/styrene/2-hydroxyethyl methacrylate copolymer, without being limited thereto. These may be used alone or in combination thereof.

The acrylic resin may have a weight average molecular weight of about 5,000 g/mol to about 15,000 g/mol. Within this range, the acrylic-based resin ensures good or suitable adhesion to a substrate, good or suitable physical and chemical properties, and suitable viscosity. In the present disclosure, a molecular weight (e.g., weight average molecular weight) of a polymer or a resin may be measured using Gel Permeation Chromatography (GPC) with a polystyrene standard.

The acrylic-based resin may have an acid value of about 80 mgKOH/g to about 130 mgKOH/g. Within this range, the acrylic-based resin may ensure good resolution of a pixel pattern.

The cardo-based resin may be any of those used in typical curable resin (or photosensitive resin) compositions, for example, those disclosed in Korean Public Patent No. 10-2018-0067243, the content of which is incorporated herein by reference, without being limited thereto.

The cardo-based resin may be prepared by mixing at least two selected from among a fluorene-containing compound, for example, 9,9-bis(4-oxiranylmethoxyphenyl) fluorene and/or the like; an anhydride compound, for example, benzene tetracarboxylic dianhydride, naphthalene tetracarboxylic dianhydride, biphenyl tetracarboxylic dianhydride, benzophenone tetracarboxylic dianhydride, pyromellitic dianhydride, cyclobutane tetracarboxylic dianhydride, perylene tetracarboxylic dianhydride, tetrahydrofuran tetracarboxylic dianhydride, tetrahydrophthalic dianhydride, and/or the like; a glycol compound, for example, ethylene glycol, propylene glycol, polyethylene glycol, and/or the like; an alcohol compound, for example, methanol, ethanol, propanol, n-butanol, cyclohexanol, benzyl alcohol, and/or the like; a solvent compound, for example, propylene glycol methyl ethyl acetate, N-methylpyrrolidone, and/or the like; a phosphorus compound, for example, triphenylphosphine; and an amine or ammonium salt compound, for example, tetramethylammonium chloride, tetraethylammonium bromide, benzyl diethylamine, triethylamine, tributylamine, benzyl triethylammonium chloride, and/or the like.

The cardo-based resin may have a weight average molecular weight of about 500 g/mol to about 50,000 g/mol, for example, about 1,000 g/mol to about 30,000 g/mol. Within this range, the cardo-based resin ensures efficient formation of a pattern without residue during production of a cured layer, and may secure a good or suitable pattern without loss of film thickness during development of the curable composition.

The cardo-based resin used as the binder resin may enhance the developability and light-curing sensitivity of the curable composition, especially a photosensitive resin composition, thereby ensuring efficient formation of fine patterns.

The epoxy-based resin is a monomer or oligomer that may be polymerized by heat, and may include a compound having a carbon-carbon unsaturated bond and a carbon-carbon cyclic bond.

The epoxy-based resin may include a bisphenol A type epoxy resin, a bisphenol F type epoxy resin, a phenol novolac type epoxy resin, a cyclic aliphatic epoxy resin, and/or an aliphatic polyglycidyl ether, without being limited thereto.

As commercially available products, the bisphenyl epoxy resin may include YX4000, YX4000H, YL6121H, YL6640, and YL6677 from Yuka Shell Epoxy Co., Ltd.; the cresol novolac type epoxy resin may include EOCN-102, EOCN-103S, EOCN-104S, EOCN-1020, EOCN-1025, and EOCN-1027 from Nippon Kayaku Co., Ltd. and Epikote 180S75 from Yuka Shell Epoxy Co., Ltd.; the bisphenol A type epoxy resin may include Epikote 1001, 1002, 1003, 1004, 1007, 1009, 1010, and 828 from Yuka Shell Epoxy Co., Ltd.; the bisphenol F type epoxy resin may include Epikote 807 and 834 from Yuka Shell Epoxy Co., Ltd.; the phenol novolac epoxy resin may include Epikote 152, 154, and 157H65 from Yuka Shell Epoxy Co., Ltd. and EPPN 201 and 202 from Nippon Kayaku Co., Ltd.; the cyclic aliphatic polyglycidyl ether may include CY175, CY177, and CY179 from Ciba-Geigy A.G., ERL-4234, ERL-4299, ERL-4221, and ERL-4206 from U.C.C., Shodyne 509 from Showa Denko Co., Ltd., Araldite CY-182, CY-192, and CY-184 from CIBA-GEIGY A.G., Epiclon 200 and 400 from Dai-Nippon Ink Kogyo Co., LTD., Epikote 871, 872, and EP1032H60 from Yuka Shell Epoxy Co., Ltd., and ED-5661 and ED-5662 from Selaniz Coating Co., Ltd.; and the aliphatic polyglycidyl ether may include Epikote 190P and 191P from Yuka Shell Epoxy Co., Ltd., Epikote 100MF from Dai-Nippon Ink Kogyo Co., LTD., and Epiol TMP from Nippon Yushi Co., LTD., and the like.

In one or more embodiments, when the curable composition is a solvent-free curable composition, the binder resin may be present in an amount of about 0.5 wt % to about 10 wt %, for example, about 1 wt % to about 5 wt %, based on the total weight of 100 wt % of the curable composition. Within this range, the binder resin may improve heat resistance and chemical resistance of the solvent-free curable composition together with storage stability.

In one or more embodiments, when the curable composition is a solvent-containing curable composition, the binder resin may be present in an amount of about 1 wt % to about 30 wt %, for example, about 3 wt % to about 20 wt %, based on the total weight of 100 wt % of the curable composition. Within this range, the binder resin may improve pattern properties, heat resistance and chemical resistance of the curable composition.

### Other Additives

To improve stability and dispersibility of the quantum dots, the curable composition according to one or more embodiments may further include a polymerization inhibitor.

The polymerization inhibitor may include a hydroquinone-based compound, a catechol-based compound, or a combination thereof, without being limited thereto. As the curable composition further includes the hydroquinone-based compound, the catechol-based compound, or a combination thereof, the polymerization inhibitor may prevent crosslinking at room temperature during exposure after printing (coating) the curable composition.

For example, the hydroquinone-based compound, the catechol-based compound, or a combination thereof may include hydroquinone, methyl hydroquinone, methoxy hydroquinone, t-butyl hydroquinone, 2,5-di-t-butyl hydroquinone, 2,5-bis(1,1-dimethylbutyl) hydroquinone, 2,5-bis(1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′)aluminum, or a combination thereof, without being limited thereto.

The hydroquinone-based compound, the catechol-based compound, or a combination thereof may be used in the form of a dispersion, and the polymerization inhibitor in the form of the dispersion may be present in an amount of about 0.001 wt % to about 3 wt %, for example, about 0.01 wt % to about 2 wt %, based on the total weight of 100 wt % of the curable composition. Within this range, the polymerization inhibitor may solve the problem of room temperature curing while preventing sensitivity degradation and surface peeling.

The curable composition according to one or more embodiments may further include malonic acid; 3-amino-1,2-propanediol; a silane-based coupling agent; a leveling agent; a fluorinated surfactant; or a combination thereof, to improve heat resistance and reliability.

For example, the curable composition according to one or more embodiments may further include a silane-based coupling agent having a reactive substituent, such as a vinyl group, a carboxyl group, a methacryloxy group, an isocyanate group, an epoxy group, and/or the like, to improve adhesion to a substrate.

The silane-based coupling agent may include, for example, trimethoxysilyl benzoic acid, γ-methacryloxypropyl trimethoxysilane, vinyl triacetoxysilane, vinyl trimethoxysilane, γ-isocyanatepropyl triethoxysilane, γ-glycidoxypropyl trimethoxysilane, β-epoxycyclohexylethyl trimethoxysilane, and/or the like. These may be used alone or as a mixture thereof.

The silane-based coupling agent may be present in an amount of about 0.01 parts by weight to about 10 parts by weight, relative to 100 parts by weight of the curable composition. Within this range, the silane-based coupling agent may ensure good or suitable properties of the curable composition in terms of adhesion, storage, and the like.

In one or more embodiments, the curable composition may further include a surfactant, for example a fluorinated surfactant, as needed, to enhance coatability and anti-defect formation effects, that is, to enhance leveling performance.

The fluorinated surfactant may have a low weight average molecular weight of about 4,000 g/mol to about 10,000 g/mol, for example, about 6,000 g/mol to about 10,000 g/mol. The fluorinated surfactant may also have a surface tension of about 18 mN/m to about 23 mN/m (as measured in a 0.1% propylene glycol monomethylether acetate (PGMEA) solution). Within these ranges of the weight average molecular weight and the surface tension, the fluorinated surfactant may further enhance leveling performance, prevent smudging during high speed coating, and reduce film defects by minimizing bubble generation, thereby imparting good or suitable properties to slit coating, which is a high-speed coating method.

The fluorinated surfactant may include BM-1000®, BM-1100®, and/or the like from BM Chemie GmbH; MEGAFACE F 142DR, F 172®, F 173®, F 183®, and/or the like from Dai Nippon Ink Kagaku Kogyo Co., Ltd.; Fluorad FC-135®, FC-170C®, FC-430®, FC-431®, and/or the like from Sumitomo 3M; SURFLON S-112®, S-113®, S-131®, S-141®, S-145®, and/or the like from Asahi Glass Co., Ltd.; SH-28PA®, S-190®, S-193®, SZ-6032®, SF-8428®, and/or the like from Toray Silicones Co., Ltd.; and/or F-482, F-484, F-478, F-554, and/or the like from DIC Corporation.

In one or more embodiments, the curable composition may include a silicone-based surfactant together with the fluorinated surfactants described above. Examples of the silicone-based surfactant may include TSF400, TSF401, TSF410, and TSF4440 from Toshiba Silicones Co., LTD., without being limited thereto.

The surfactant, including the fluorinated surfactant and/or the like, may be present in an amount of about 0.01 parts by weight to about 5 parts by weight, for example, about 0.1 parts by weight to about 2 parts by weight, relative to 100 parts by weight of the curable composition. Within this range, the surfactant may minimize generation of foreign matter in the sprayed composition.

The curable composition according to one or more embodiments may also contain a certain amount of other additives, such as an antioxidant, without impairing the properties of the curable composition.

### Solvent

The curable composition according to one or more embodiments may further include a solvent.

The solvents include, for example, one or more selected from among alcohols, such as methanol, ethanol, and the like; glycol ethers, such as ethylene glycol methyl ether, ethylene glycol ethyl ether, propylene glycol methyl ether, and the like; cellosolve acetates, such as methyl cellosolve acetate, ethyl cellosolve acetate, diethyl cellosolve acetate, and the like; carbitols, such as methyl ethyl carbitol, diethyl carbitol, diethylene glycol monomethyl ether, diethylene glycol monoethyl ether, diethylene glycol dimethyl ether, diethylene glycol methyl ethyl ether, diethylene glycol diethyl ether, and the like; propylene glycol alkyl ether acetates, such as propylene glycol monomethyl ether acetate, propylene glycol propyl ether acetate; ketones, such as methyl ethyl ketone, cyclohexanone, 4-hydroxy-4-methyl-2-pentanone, methyl-n-propyl ketone, methyl-n-butyl ketone, methyl-n-amyl ketone, 2-heptanone, and the like; alkyl esters of saturated aliphatic monocarboxylic acids, such as ethyl acetate, n-butyl acetate, isobutyl acetate, and the like; alkyl esters of lactic acid, such as methyl lactate, ethyl lactate, and the like; alkyl esters of hydroxyacetic acid, such as methyl hydroxyacetate, ethyl hydroxyacetate, butyl hydroxyacetate, and the like; alkoxyalkyl esters of acetic acid, such as methoxymethyl acetate, methoxyethyl acetate, methoxybutyl acetate, ethoxymethyl acetate, ethoxyethyl acetate, and the like; alkyl esters of 3-hydroxypropionic acid, such as methyl 3-hydroxypropionate, ethyl 3-hydroxypropionate, and the like; alkyl esters of 3-alkoxypropionic acids, such as methyl 3-methoxypropionate, ethyl 3-methoxypropionate, ethyl 3-ethoxypropionate, methyl 3-ethoxypropionate, and the like; alkyl esters of 2-hydroxypropionic acids, such as methyl 2-hydroxypropionate, ethyl 2-hydroxypropionate, propyl 2-hydroxypropionate, and the like; alkyl esters of 2-alkoxypropionic acids, such as methyl 2-methoxypropionate, ethyl 2-methoxypropionate, ethyl 2-ethoxypropionate, methyl 2-ethoxypropionate, and the like; alkyl esters of 2-hydroxy-2-methylpropionic acids, such as methyl 2-hydroxy-2-methylpropionate, ethyl 2-hydroxy-2-methylpropionate, and the like; alkyl esters of 2-alkoxy-2-methylpropionic acids, such as methyl 2-methoxy-2-methylpropionate, ethyl 2-ethoxy-2-methylpropionate, and the like; esters, such as 2-hydroxyethyl propionate, 2-hydroxy-2-methylethyl propionate, hydroxyethyl acetate, methyl 2-hydroxy-3-methylbutanoate, and the like; ketone acid esters, such as ethyl pyruvate and the like; and N-methyl formamide, N, N-dimethyl formamide, N-methyl formanilide, N-methyl formamide, N-methyl acetamide, N, N-dimethyl acetamide, N-methyl pyrrolidone, dimethyl sulfoxide, benzyl ethyl ether, dihexyl ether, acetyl acetone, isophorone, capric acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and the like, without being limited thereto.

For example, in one or more embodiments, the solvent may include at least one selected from the group consisting of glycol ethers, such as ethylene glycol monoethyl ether, ethylene diglycol methylethyl ether, and the like; ethylene glycol alkyl ether acetates, such as ethyl cellosolve acetate and the like; esters, such as ethyl 2-hydroxypropionic acid and the like; carbitols, such as diethylene glycol monomethyl ether and the like; propylene glycol alkyl ether acetates, such as propylene glycol monomethyl ether acetate, propylene glycol propyl ether acetate, and the like; alcohols, such as ethanol and the like; cyclohexyl acetate, and combinations thereof.

For example, in one or more embodiments, the solvent may be a polar solvent of high boiling point, including propylene glycol monomethyl ether acetate, dipropylene glycol methyl ether acetate, ethanol, ethylene glycol dimethylether, ethylene diglycol methyl ether, diethylene glycol dimethyl ether, 2-butoxyethanol, N-methylpyrrolidine, N-ethylpyrrolidine, propylene carbonate, γ-butyrolactone, cyclohexyl acetate, or a combination thereof.

The solvent may be present in an amount of about 40 wt % to about 80 wt %, for example, about 45 wt % to about 80 wt %, based on the total weight of 100 wt % of the curable composition. Within this range, the solvent ensures suitable viscosity of the solvent-containing curable composition, thereby securing good or suitable coating properties for spin coating and large area coating using slits.

One or more embodiments of the present disclosure further provide a cured layer produced from the curable composition, a color filter including the cured layer, and a display device including the color filter. For example, the display device may include a micro-LED light source.

In one or more embodiments, the display device may include a color filter layer including the cured layer. According to one or more embodiments, the display device may be a light emitting diode display including an organic light emitting display.

The drawing is a cross-sectional view of a light emitting diode display device according to one or more embodiments of the present disclosure.

Referring to the drawing, the display device 11 according to one or more embodiments includes a light source 10, which includes a first substrate 111, two or more first electrodes 112 formed on the first substrate 111, a pixel-defining layer 113 formed between adjacent first electrodes 112, an organic light emitting layer 120 formed on each of the first electrodes 112 and emitting a first light, a second electrode layer 114 formed on the organic light emitting layer 120 (120a, 120b, and 120c), and a first planarization layer 115 formed on the second electrode layer 114; a sealing layer 119 formed on the first planarization layer 115; a second planarization layer 118 formed on the sealing layer 119; a color filter layer 130 (130r, 130g, and 130b), which includes quantum dots 3r, 3g formed on the second planarization layer 118 and converting the first light into at least one of a second light or a third light different from each other; and a second substrate 116 formed on the color filter layer 130.

In the display device 11 according to one or more embodiments, the organic light emitting layer 120 may be defined as a first pixel region, a second pixel region, and a third pixel region, each of which is spaced and/or apart at a predetermined interval by the pixel-defining layer 113. In one or more embodiments, unit layers belonging to the first to third pixel regions of the organic light emitting layer 120 are defined as first to third organic light emitting layers 120a to 120c, respectively.

The color filter layer 130 is formed to cover a region between adjacent light-shielding members 117. The color filter layer 130 may include first to third color filters 130r, 130g, 130b formed at locations that overlap with the first to third pixel regions described above, respectively.

In one or more embodiments, the first color filter 130r including the quantum dots 3r may emit the second light different from the first light, the second color filter 130g including the quantum dots 3g may emit the third light different from the first light, and the third color filter 130b may emit the first light. For example, the first light may be blue color light, the second light may be red color light, and the third light may be green color light.

In one or more embodiments, the display device 11 may further include a color conversion layer.

A method of forming a cured layer according to one or more embodiments may include: forming a pattern by applying the curable composition to a substrate by an inkjet spraying method (S1); and curing the pattern (S2).

### (S1) Pattern Formation Step

In one or more embodiments, the curable composition is deposited to a thickness of about 0.5 μm to about 20 μm on the substrate by the inkjet spraying method. In the inkjet spraying method, the pattern may be formed by repeatedly spraying curable compositions each with only a single color through each nozzle corresponding to a preset number of colors. In one or more embodiments, to reduce the number of processes, the pattern may be formed by simultaneously spraying a preset number of colors through corresponding inkjet nozzles.

### (S2) Curing Step

Pixels may be obtained by curing the pattern obtained above. Here, either a thermal curing process or a photocuring process may be applied as a curing method. The thermal curing process may be performed by heating to a temperature of about 100 °C or higher, for example, to a temperature of about 100 °C to about 300 °C, for example, to a temperature of about 160 °C to about 250 °C. The photocuring process may be performed by irradiation with actinic radiation light, for example, UV light with a wavelength of about 190 nm to about 450 nm, for example, about 200 nm to about 400 nm. As a light source for irradiation, a low pressure mercury lamp, a high pressure mercury lamp, an ultra-high pressure mercury lamp, a metal halide lamp, an argon gas laser, i-lines, KrF, ArF, I-ArF, EUV, X-rays, and/or electron rays may be used.

According to one or more embodiments of the present disclosure, in another method of forming a cured layer, the cured layer may be formed by a lithography process using the curable composition. The method may be as follows.

### (1) Deposition and Film Formation Step

The curable composition is deposited to a predetermined thickness, for example, a thickness of about 2 μm to about 10 μm, on a substrate that has been subjected to a predetermined pretreatment, using a process, such as a spin or slit coating process, a roll coating process, a screen printing process, an applicator process, or the like, and is then heated at a temperature of about 70 °C to about 90 °C for about 1 minute to about 10 minutes to form a coating film through removal of the solvent.

### (2) Exposure Step

After placing a mask of a predetermined shape to form a predetermined pattern on the coating film, the coating film is irradiated with actinic radiation light, for example, UV light with a wavelength of about 190 nm to about 450 nm, for example, about 200 nm to about 400 nm. As a light source for irradiation, a low pressure mercury lamp, a high pressure mercury lamp, an ultra-high pressure mercury lamp, a metal halide lamp, an argon gas laser, i-lines, KrF, ArF, I-ArF, EUV, X-rays, and/or electron rays may be used.

The exposure dose depends on the type and amount of each component of the curable composition and the dry film thickness. However, for example, in one or more embodiments, exposure with a high-pressure mercury lamp may be performed at a dose of about 500 mJ/cm² or less (by a 365 nm sensor).

(3) Development step

After the exposure step, an unnecessary part (e.g., unexposed part) is dissolved and removed in an alkaline aqueous solution used as a developer such that only the exposed region remains, thereby forming an image pattern. That is, when developing with an alkaline developer, the non-exposed part is dissolved, and an image color filter pattern is formed.

### (4) Post-Processing Step

The image pattern obtained through the development step may be cured by reheating or irradiation with actinic radiation light to obtain a pattern that has good or suitable properties in terms of heat resistance, light resistance, adhesion, crack resistance, chemical resistance, high strength, storage stability, and/or the like.

Next, the present disclosure will be further described in more detail with reference to some examples. It should be understood that these examples are provided for illustration only and are not to be construed in any way as limiting the disclosure.

### Synthesis of Surface Modifier

### First Ligand

### Comparative Synthesis Example 1

A commercially available reagent (Sigma-Aldrich GmbH) represented by Ligand 2 was used.

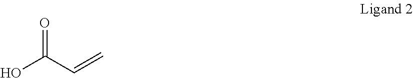

### Synthesis Example 1-1

A commercially available reagent (Sigma-Aldrich GmbH) represented by Ligand 3 was used.

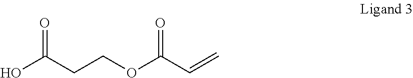

### Synthesis Example 1-2

In a round bottom flask, 19.6 g of cyclobutane-1,2,3,4-tetracarboxylic dianhydride, 23.2 g of 2-hydroxyethyl acrylate, 0.4 g of tetrabutylammonium bromide, and 0.01 g of hydroquinone were reacted at 95 °C for 15 hours, thereby preparing a compound represented by Ligand 4.

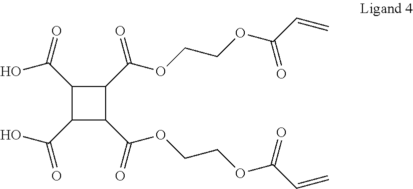 [SMILES: C=CC(=O)OCCOC(=O)C1C(C(=O)O)C(C(=O)O)C1C(=O)OCCOC(=O)C=C]

### Synthesis Example 1-3

In a round bottom flask, 14.2 g of glycidyl methacrylate, 8.6 g of methacrylic acid, 0.4 g of tetrabutylammonium bromide, and 0.01 g of hydroquinone were reacted at 90 °C for 15 hours. 10 g of succinic anhydride was further added to the resulting mixture and reacted at 95 °C for 15 hours, thereby preparing a compound represented by Ligand 5.

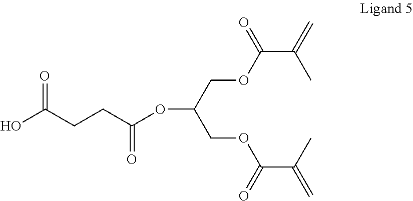 [SMILES: C=C(C)C(=O)OCC(COC(=O)C(=C)C)OC(=O)CCC(=O)O]

### Synthesis Example 1-4

In a round bottom flask, 14.2 g of glycidyl methacrylate, 7.2 g of acrylic acid, 0.4 g of tetrabutylammonium bromide, and 0.01 g of hydroquinone were reacted at 90 °C for 15 hours. 10 g of succinic anhydride was further added to the resulting mixture and reacted at 95 °C for 15 hours, thereby preparing a compound represented by Ligand 6.

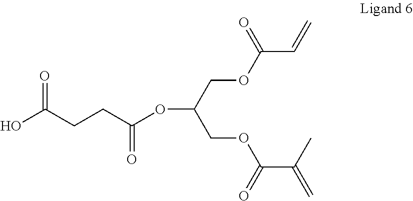 [SMILES: C=CC(=O)OCC(COC(=O)C(=C)C)OC(=O)CCC(=O)O]

### Synthesis Example 1-5

In a round bottom flask, 11.4 g of allyl glycidyl ether, 7.2 g of acrylic acid, 0.4 g of tetrabutylammonium bromide, and 0.01 g of hydroquinone were reacted at 90 °C for 15 hours. 10 g of succinic anhydride was further added to the resulting mixture and reacted at 95 °C for 15 hours, thereby preparing a compound represented by Ligand 7.

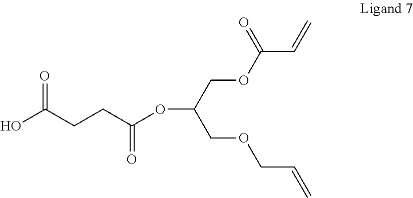 [SMILES: C=CCOCC(COC(=O)C=C)OC(=O)CCC(=O)O]

### Synthesis Examples 1-6

In a round bottom flask, 14.2 g of glycidyl methacrylate, 8.6 g of methacrylic acid, 0.4 g of tetrabutylammonium bromide, and 0.01 g of hydroquinone were reacted at 90 °C for 15 hours. 9.8 g of maleic anhydride was further added to the resulting mixture and reacted at 95 °C for 15 hours, thereby preparing a compound represented by Ligand 8.

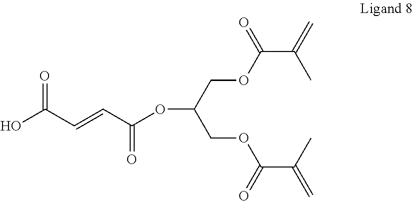 [SMILES: C=C(C)C(=O)OCC(COC(=O)C(=C)C)OC(=O)/C=C/C(=O)O]

### Synthesis Examples 1-7

In a round bottom flask, 14.2 g of glycidyl methacrylate, 8.6 g of methacrylic acid, 0.4 g of tetrabutylammonium bromide, and 0.01 g of hydroquinone were reacted at 90 °C for 15 hours. 14.0 g of allyl succinic anhydride was further added to the resulting mixture and reacted at 95 °C for 15 hours, thereby preparing a compound represented by Ligand 9.

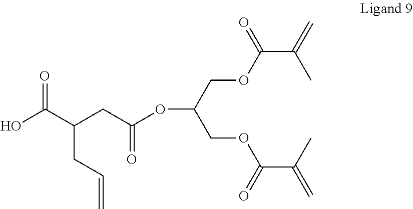 [SMILES: C=CCC(CC(=O)OC(COC(=O)C(=C)C)COC(=O)C(=C)C)C(=O)O]

### Synthesis Examples 1-8

In a round bottom flask, 14.2 g of glycidyl methacrylate, 8.6 g of methacrylic acid, 0.4 g of tetrabutylammonium bromide, and 0.01 g of hydroquinone were reacted at 90 °C for 15 hours. 14.0 g of glutaric anhydride was further added to the resulting mixture and reacted at 95 °C for 15 hours, thereby preparing a compound represented by Ligand 10.

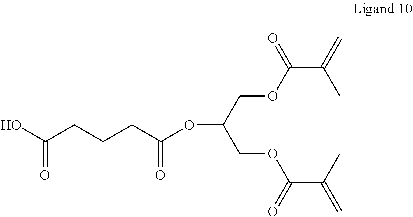 [SMILES: C=C(C)C(=O)OCC(COC(=O)C(=C)C)OC(=O)CCCC(=O)O]

### Synthesis Examples 1-9

14.2 g of glycidyl methacrylate, 8.6 g of methacrylic acid, 0.4 g of tetrabutylammonium bromide, and 0.01 g of hydroquinone were reacted at 90 °C for 15 hours. 11.6 g of diglycolic anhydride was further added to the resulting mixture and reacted at 95 °C for 15 hours, thereby preparing a compound represented by Ligand 11.

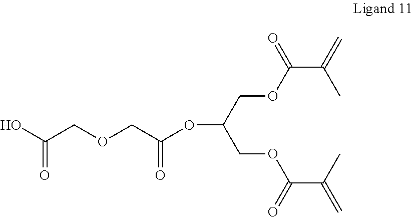 [SMILES: C=C(C)C(=O)OCC(COC(=O)C(=C)C)OC(=O)COCC(=O)O]

### Second Ligand

### Comparative Synthesis Example 2

128 g of methoxy polyethylene glycol ether (Hannong Chemical Co., Ltd.; having a methoxy terminal group and a hydroxyl terminal group; average repeat unit number n≈3) was sufficiently dissolved in 300 mL of tetrahydrofuran (THF) in a two-neck round-bottom flask. 15.4 g of NaOH and 100 ml of water were further added to the resulting solution at 0 °C, followed by sufficiently dissolving until a clear solution was obtained. Then, a solution of 73 g of para-toluene sulfonyl chloride dissolved in 100 mL of THF was slowly added to the resulting solution at 0 °C. Addition was performed for 1 hour, followed by stirring at room temperature for 12 hours. After reaction was completed, an excess of methylene chloride was added to the resulting solution and stirred, followed by extraction, washing/neutralization, and removal of water with a saturated NaHCO₃ solution. After removing the solvent, the resulting product was dried in a dry oven for 24 hours. 50 g of the obtained dry product was placed in the two-neck round-bottom flask and sufficiently stirred in 300 mL of ethanol. Then, 27 g of thiourea was added to the flask and dispersed therein, followed by refluxing at 80 °C for 12 hours. 4.4 g of a NaOH solution dissolved in 20 ml of water was added to the resulting product and an excess of methylene chloride was further added thereto while stirring for 5 hours, followed by sequentially performing extraction, washing/neutralization, removal of water, and removal of the solvent with an aqueous hydrochloric acid solution. The resulting product was dried in a vacuum oven for 24 hours, thereby preparing a compound represented by Ligand 0.

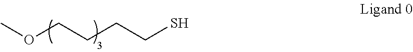

### Synthesis Example 2

100 g of polyethylene glycol phenyl ether (Hannong Chemical Co., Ltd.) was sufficiently dissolved in 300 mL of THE in a two-neck round-bottom flask. 15.4 g of NaOH and 100 mL of water were further added to the resulting solution at 0 °C, followed by sufficiently dissolving until a clear solution was obtained. Then, a solution of 73 g of para-toluene sulfonyl chloride dissolved in 100 mL of THF was slowly added to the resulting solution at 0 °C. Addition was performed for 1 hour, followed by stirring at room temperature for 12 hours. After reaction was completed, an excess of methylene chloride was added to the resulting solution and stirred, followed by extraction, titration, and removal of moisture with a saturated NaHCO₃ solution. After removing the solvent, the resulting product was dried in a dry oven for 24 hours. 50 g of the obtained dry product was placed in the two-neck round-bottom flask and sufficiently stirred in 300 mL of ethanol. Then, 27 g of thiourea was added to the flask and dispersed therein, followed by refluxing at 80 °C for 12 hours. 4.4 g of a NaOH solution dissolved in 20 ml of water was added to the resulting product and an excess of methylene chloride was further added thereto while stirring for 5 hours, followed by sequentially performing extraction, titration, removal of water, and removal of the solvent with an aqueous hydrochloric acid solution. The resulting product was dried in a vacuum oven for 24 hours, thereby preparing a compound represented by Ligand 1.

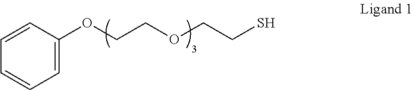

### Preparation of Surface-Modified Quantum Dots

### Preparative Example

With a magnetic bar placed in a three-necked round-bottom flask, a green quantum dot dispersion (InP/ZnSe/ZnS, Shouwei Chemical Co., Ltd.; quantum dot solids: 26 wt %) was added to the flask. A primary ligand (first ligand, i.e., one of Ligands 3 to 11) was added thereto and stirred at 60 °C under a nitrogen atmosphere, and a secondary ligand (second ligand, i.e., Ligand 1) was added together with ZnCl₂ and stirred at 60 °C under a nitrogen atmosphere. After completion of reaction, the resulting product was cooled to room temperature (23 °C), and the quantum dot reaction solution was added to cyclohexane to obtain precipitates. The precipitates were separated from cyclohexane by centrifugation and then dried in a vacuum oven for 1 day, thereby preparing surface-modified quantum dots.

### Comparative Examples

Quantum dots were prepared in substantially the same manner as in Preparative Example except that the primary ligand and/or the secondary ligand were changed.

The compositions of the prepared quantum dots are shown in Table 1.

TABLE 1

| | | Secondary | Content ratio (weight |
|---|---|---|---|
| | Primary Ligand | Ligand | ratio) |
| Comparative | Ligand 0 | — | 1:1 |
| Example 1 | | | |
| Comparative | Ligand 1 | — | 1:1 |
| Example 2 | | | |
| Comparative | Ligand 2 | — | 1:1 |
| Example 3 | | | |
| Comparative | Ligand 3 | — | 1:1 |
| Example 4 | | | |
| Comparative | Ligand 5 | — | 1:1 |
| Example 5 | | | |
| Comparative | Ligand 2 | Ligand 0 | 1:1 |
| Example 6 | | | |
| Comparative | Ligand 2 | Ligand 1 | 1:1 |
| Example 7 | | | |
| Example 1 | Ligand 3 | Ligand 1 | 1:1 |
| Example 2 | Ligand 4 | Ligand 1 | 1:1 |
| Example 3 | Ligand 5 | Ligand 1 | 1:1 |
| Example 4 | Ligand 6 | Ligand 1 | 1:1 |
| Example 5 | Ligand 7 | Ligand 1 | 1:1 |
| Example 6 | Ligand 8 | Ligand 1 | 1:1 |
| Example 7 | Ligand 9 | Ligand 1 | 1:1 |
| Example 8 | Ligand 10 | Ligand 1 | 1:1 |
| Example 9 | Ligand 11 | Ligand 1 | 1:1 |
| Example 10 | Ligand 5 | Ligand 1 | 0.5:1 |
| Example 11 | Ligand 5 | Ligand 1 | 1.5:1 |

### Preparation of Solvent-Free Curable Composition

Solvent-free curable compositions were each prepared using the following components.

### (A) Quantum Dots

Respective Quantum dots as shown in Table 1

### (B) Polymerizable Compound

Compound represented by Formula 3-2 (M200, Miwon Chemical Co., Ltd.)

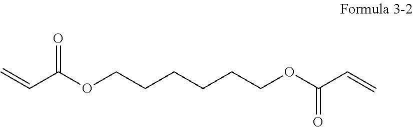 [SMILES: C=CC(=O)OCCCCCCOC(=O)C=C]

### (C) Photopolymerization Initiator

TPO-L (ethyl phenyl(2,4,6-trimethylbenzoyl)phosphinate) (from Polynetron)

### (D) Light Diffusing Agent

Titanium dioxide dispersion (rutile type TiO₂; D50 (180 nm), 50 wt % solids, from Iridos Co., Ltd.)

The surface-modified quantum dots and the polymerizable compound were mixed and stirred sufficiently. Then, the photopolymerization initiator and the light diffusing agent were sequentially added to the resulting mixture, followed by stirring, thereby preparing respective curable compositions (ink) (quantum dot dispersion solids: 50 wt %).

Details of each of the prepared curable compositions (ink) are shown in Tables 2 and 3 (unit: wt %).

TABLE 2

| | | Comparative Example | | | | | | | Example | | |
|---|---|---|---|---|---|---|---|---|---|---|---|
| QD ink | | 1 | 2 | 3 | 4 | 5 | 6 | 7 | 1 | 2 | 3 |
| (A) | | 82 | 82 | 82 | 82 | 82 | 82 | 82 | 82 | 82 | 82 |
| QD dispersion | | | | | | | | | | | |
| (A) | Ligand | ⊚ | | | | | ⊚ | | | | |
| QD | 0 | | | | | | | | | | |
| disper- | Ligand | | ⊚ | | | | | ⊚ | ⊚ | ⊚ | ⊚ |
| sion | 1 | | | | | | | | | | |
| | Ligand | | | ⊚ | | | ⊚ | ⊚ | | | |
| | 2 | | | | | | | | | | |
| | Ligand | | | | ⊚ | | | | ⊚ | | |
| | 3 | | | | | | | | | | |
| | Ligand | | | | | | | | | ⊚ | |
| | 4 | | | | | | | | | | |
| | Ligand | | | | | ⊚ | | | | | ⊚ |
| | 5 | | | | | | | | | | |
| | Ligand | | | | | | | | | | |
| | 6 | | | | | | | | | | |
| | Ligand | | | | | | | | | | |
| | 7 | | | | | | | | | | |
| | Ligand | | | | | | | | | | |
| | 8 | | | | | | | | | | |
| | Ligand | | | | | | | | | | |
| | 9 | | | | | | | | | | |
| | Ligand | | | | | | | | | | |
| | 10 | | | | | | | | | | |
| | Ligand | | | | | | | | | | |
| | 11 | | | | | | | | | | |

| | | | | | | | | | | |
|---|---|---|---|---|---|---|---|---|---|---|
| (B) | 7 | 7 | 7 | 7 | 7 | 7 | 7 | 7 | 7 | 7 |
| Dispersion | | | | | | | | | | |
| monomer | | | | | | | | | | |
| (C) | | | | | | | | | | |
| Photopoly- | 3 | 3 | 3 | 3 | 3 | 3 | 3 | 3 | 3 | 3 |
| merization | | | | | | | | | | |
| initiator | | | | | | | | | | |
| (D) | 8 | 8 | 8 | 8 | 8 | 8 | 8 | 8 | 8 | 8 |
| Light | | | | | | | | | | |
| diffusing | | | | | | | | | | |
| agent | | | | | | | | | | |
| Total | 100 | 100 | 100 | 100 | 100 | 100 | 100 | 100 | 100 | 100 |

TABLE 3

| | | Example | | | | | | | |
|---|---|---|---|---|---|---|---|---|---|
| QD ink | | 4 | 5 | 6 | 7 | 8 | 9 | 10 | 11 |
| (A) QD dispersion | | 82 | 82 | 82 | 82 | 82 | 82 | 82 | 82 |
| (A) QD | Ligand 0 | | | | | | | | |
| dispersion | Ligand 1 | ⊚ | ⊚ | ⊚ | ⊚ | ⊚ | ⊚ | ⊚ | ⊚ |
| | Ligand 2 | | | | | | | | |
| | Ligand 3 | | | | | | | | |
| | Ligand 4 | | | | | | | | |
| | Ligand 5 | | | | | | | ⊚ | ⊚ |
| | Ligand 6 | ⊚ | | | | | | | |
| | Ligand 7 | | ⊚ | | | | | | |
| | Ligand 8 | | | ⊚ | | | | | |
| | Ligand 9 | | | | ⊚ | | | | |
| | Ligand 10 | | | | | ⊚ | | | |
| | Ligand 11 | | | | | | ⊚ | | |

| | | | | | | | | |
|---|---|---|---|---|---|---|---|---|
| (B) Dispersion | 7 | 7 | 7 | 7 | 7 | 7 | 7 | 7 |
| monomer | | | | | | | | |
| (C) | 3 | 3 | 3 | 3 | 3 | 3 | 3 | 3 |
| Photopolymerization | | | | | | | | |
| initiator | | | | | | | | |
| (D) Light diffusing | 8 | 8 | 8 | 8 | 8 | 8 | 8 | 8 |
| agent | | | | | | | | |
| Total | 100 | 100 | 100 | 100 | 100 | 100 | 100 | 100 |

### Preparation of Solvent-Containing Curable Composition

Solvent-containing curable compositions were each prepared using the following components.

### (A) Quantum Dots

Quantum dots having the same composition as shown in Table 1

### (B) Polymerizable Compound

Dipentaerythritol hexaacrylate (DPHA, from Nippon Kayaku Co., Ltd.)

### (C) Photopolymerization Initiator

Oxime initiator (PBG-305, from Tronyl Co., Ltd.)

### (D) Light Diffusing Agent

Titanium dioxide dispersion (rutile type TiO₂; D50 (180 nm), 50 wt % solids, from Iridos Co., Ltd.)

### (E) Binder Resin

TA-001 (Tacoma Co., Ltd.)

### (F) Solvent

(F-1) Cyclohexyl acetate (from Sigma-Aldrich GmbH)

(F-2) Propylene glycol monomethyl ether acetate (PGMEA) (from Sigma-Aldrich GmbH)

The surface-modified quantum dots, the polymerizable compound, the binder resin, and the solvent were mixed and stirred sufficiently. Then, the photopolymerization initiator and the light diffusing agent were sequentially added to the resulting mixture, followed by stirring, thereby preparing respective curable compositions (ink) (quantum dot dispersion solids: 50 wt %).

Details of each of the prepared curable compositions (ink) are shown in Tables 4 and 5 (unit: wt %).

TABLE 4

| | | Comparative Example | | | | | | | Example | | |
|---|---|---|---|---|---|---|---|---|---|---|---|
| QD ink | | 1 | 2 | 3 | 4 | 5 | 6 | 7 | 1 | 2 | 3 |
| (A) QD dispersion | | 54.67 | 54.67 | 54.67 | 54.67 | 54.67 | 54.67 | 54.67 | 54.67 | 54.67 | 54.67 |
| (A) QD | Ligand | ⊚ | | | | | ⊚ | | | | |
| dispersion | 0 | | | | | | | | | | |
| | Ligand | | ⊚ | | | | | ⊚ | ⊚ | ⊚ | ⊚ |
| | 1 | | | | | | | | | | |
| | Ligand | | | ⊚ | | | ⊚ | ⊚ | | | |
| | 2 | | | | | | | | | | |
| | Ligand | | | | ⊚ | | | | ⊚ | | |
| | 3 | | | | | | | | | | |
| | Ligand | | | | | | | | | ⊚ | |
| | 4 | | | | | | | | | | |
| | Ligand | | | | | ⊚ | | | | | ⊚ |
| | 5 | | | | | | | | | | |
| | Ligand | | | | | | | | | | |
| | 6 | | | | | | | | | | |
| | Ligand | | | | | | | | | | |
| | 7 | | | | | | | | | | |
| | Ligand | | | | | | | | | | |
| | 8 | | | | | | | | | | |
| | Ligand | | | | | | | | | | |
| | 9 | | | | | | | | | | |
| | Ligand | | | | | | | | | | |
| | 10 | | | | | | | | | | |
| | Ligand | | | | | | | | | | |
| | 11 | | | | | | | | | | |

| | | | | | | | | | | |
|---|---|---|---|---|---|---|---|---|---|---|
| (B) Dispersion | 7.97 | 7.97 | 7.97 | 7.97 | 7.97 | 7.97 | 7.97 | 7.97 | 7.97 | 7.97 |
| monomer | | | | | | | | | | |
| (C) | 0.33 | 0.33 | 0.33 | 0.33 | 0.33 | 0.33 | 0.33 | 0.33 | 0.33 | 0.33 |
| Photopolymer- | | | | | | | | | | |
| ization initiator | | | | | | | | | | |
| (D) Light diffusing | 2.67 | 2.67 | 2.67 | 2.67 | 2.67 | 2.67 | 2.67 | 2.67 | 2.67 | 2.67 |
| agent | | | | | | | | | | |
| (E) Binder resin | 20 | 20 | 20 | 20 | 20 | 20 | 20 | 20 | 20 | 20 |
| (F) Solvent | 14.33 | 14.33 | 14.33 | 14.33 | 14.33 | 14.33 | 14.33 | 14.33 | 14.33 | 14.33 |
| (G) Other | 0.03 | 0.03 | 0.03 | 0.03 | 0.03 | 0.03 | 0.03 | 0.03 | 0.03 | 0.03 |
| additives | | | | | | | | | | |
| Total | 100 | 100 | 100 | 100 | 100 | 100 | 100 | 100 | 100 | 100 |

TABLE 5

| | | Example | | | | | | | |
|---|---|---|---|---|---|---|---|---|---|
| QD ink | | 4 | 5 | 6 | 7 | 8 | 9 | 10 | 11 |
| (A) | | 54.67 | 54.67 | 54.67 | 54.67 | 54.67 | 54.67 | 54.67 | 54.67 |
| QD dispersion | | | | | | | | | |
| (A) QD | Ligand 0 | | | | | | | | |
| dispersion | Ligand 1 | ⊚ | ⊚ | ⊚ | ⊚ | ⊚ | ⊚ | ⊚ | ⊚ |
| | Ligand 2 | | | | | | | | |
| | Ligand 3 | | | | | | | | |
| | Ligand 4 | | | | | | | | |
| | Ligand 5 | | | | | | | ⊚ | ⊚ |
| | Ligand 6 | ⊚ | | | | | | | |
| | Ligand 7 | | ⊚ | | | | | | |
| | Ligand 8 | | | ⊚ | | | | | |
| | Ligand 9 | | | | ⊚ | | | | |
| | Ligand 10 | | | | | ⊚ | | | |
| | Ligand 11 | | | | | | ⊚ | | |

| | | | | | | | | |
|---|---|---|---|---|---|---|---|---|
| (B) Dispersion | 7.97 | 7.97 | 7.97 | 7.97 | 7.97 | 7.97 | 7.97 | 7.97 |
| monomer | | | | | | | | |
| (C) | 0.33 | 0.33 | 0.33 | 0.33 | 0.33 | 0.33 | 0.33 | 0.33 |
| Photopolymerization | | | | | | | | |
| initiator | | | | | | | | |
| (D) Light diffusing | 2.67 | 2.67 | 2.67 | 2.67 | 2.67 | 2.67 | 2.67 | 2.67 |
| agent | | | | | | | | |
| (E) Binder resin | 20 | 20 | 20 | 20 | 20 | 20 | 20 | 20 |
| (F) Solvent | 14.33 | 14.33 | 14.33 | 14.33 | 14.33 | 14.33 | 14.33 | 14.33 |
| (G) Other additives | 0.03 | 0.03 | 0.03 | 0.03 | 0.03 | 0.03 | 0.03 | 0.03 |
| Total | 100 | 100 | 100 | 100 | 100 | 100 | 100 | 100 |

### Evaluation 1: Quantum Efficiency Evaluation

Quantum efficiency was evaluated for each of the solvent-free curable compositions (inks) prepared in Examples 1 to 11 and Comparative Examples 1 to 7, and the solvent-containing curable compositions (PRs) prepared in Examples 1 to 11 and Comparative Examples 1 to 7.

### Evaluation of Quantum Efficiency

EQE (external quantum efficiency, unit: %): Each of the quantum dot compositions prepared in Examples and Comparative Examples was deposited to a thickness of 7 μm on a glass substrate using a spin coater (Opticoat MS-A150, Mikasa Co., Ltd.), followed by exposure at a dose of 5000 mJ/cm² using an exposure machine (wavelength: 395 nm) under a nitrogen atmosphere to form a film (EXP).

For the PR compositions (i.e., solvent-containing curable compositions), the solvent was removed at 100 °C for 1 min before curing the film, followed by exposure using the exposure machine.

The films were cured (POB) at 180 °C under a nitrogen atmosphere for 30 min and cooled for 1 hour. Then, EQE was evaluated for each of the films (2 cm×2 cm) in an integral hemisphere quantum efficiency meter (QE-2000, Otsuka Co., Ltd.).

### Evaluation 2: Evaluation of Light Resistance of Curable Composition

Light resistance was evaluated for each of the solvent-free curable compositions (ink) prepared in Examples 1 to 11 and Comparative Examples 1 to 7, and the solvent-containing curable compositions (PRs) prepared in Examples 1 to 11 and Comparative Examples 1 to 7.

### Evaluation of Light Resistance

Luminance variation of a blue LED chip per hour was measured at 105,000 nits using an in-line luminance meter (M7000, McScience).

Light resistance was evaluated by comparing T90 values based on an initial value 100% and results are shown in Table 1. As used herein, the term “T90” refers to the time (in hours) taken for the luminance of a coating film decreasing from its initial value to 90% of it under above measurement conditions.

### Results of Evaluations 1 and 2 are Shown in Table 6.

TABLE 6

| | | | Quantum efficiency | | | | Reliability | |
|---|---|---|---|---|---|---|---|---|
| | Ligand | | (%) | | | | (hr@T90)* | |
| | | Secon- | QD ink | | QD PR | | QD | QD |
| | Primary | dary | EXP | POB | EXP | POB | ink | PR |
| Compar- | Ligand | | 31.0 | 26.1 | 31.1 | 26.5 | 10 | 5 |
| ative | 0 | | | | | | | |
| Exam- | | | | | | | | |
| ple 1 | | | | | | | | |
| Compar- | Ligand | | 31.8 | 31.9 | 31.5 | 31.0 | 46 | 30 |
| ative | 1 | | | | | | | |
| Exam- | | | | | | | | |
| ple 2 | | | | | | | | |
| Compar- | Ligand | | 31.0 | 27.1 | 31.2 | 26.5 | 11 | 5 |
| ative | 2 | | | | | | | |
| Exam- | | | | | | | | |
| ple 3 | | | | | | | | |
| Compar- | Ligand | | 31.1 | 25.3 | 31.0 | 25.3 | 12 | 5 |
| ative | 3 | | | | | | | |
| Exam- | | | | | | | | |
| ple 4 | | | | | | | | |
| Compar- | Ligand | | 31.0 | 26.3 | 31.3 | 21.3 | 80 | 24 |
| ative | 5 | | | | | | | |
| Exam- | | | | | | | | |
| ple 5 | | | | | | | | |
| Compar- | Ligand | Ligand | 31.1 | 28.5 | 31.1 | 28.1 | 100 | 58 |
| ative | 2 | 0 | | | | | | |
| Exam- | | | | | | | | |
| ple 6 | | | | | | | | |
| Compar- | Ligand | Ligand | 31.5 | 31.4 | 32.0 | 32.0 | 120 | 63 |
| ative | 2 | 1 | | | | | | |
| Exam- | | | | | | | | |
| ple 7 | | | | | | | | |
| Exam- | Ligand | Ligand | 32.6 | 32.5 | 31.0 | 31.2 | 1,020 | 494 |
| ple 1 | 3 | 1 | | | | | | |
| Exam- | Ligand | Ligand | 29.5 | 26.5 | 29.8 | 28.4 | 340 | 200 |
| ple 2 | 4 | 1 | | | | | | |
| Exam- | Ligand | Ligand | 33.2 | 33.0 | 33.2 | 33.2 | 2,650 | 860 |
| ple 3 | 5 | 1 | | | | | | |
| Exam- | Ligand | Ligand | 32.6 | 32.8 | 33.1 | 33.0 | 2,400 | 840 |
| ple 4 | 6 | 1 | | | | | | |
| Exam- | Ligand | Ligand | 32.6 | 32.6 | 32.5 | 32.4 | 2,300 | 802 |
| ple 5 | 7 | 1 | | | | | | |
| Exam- | Ligand | Ligand | 33.1 | 33.0 | 32.4 | 32.4 | 2,008 | 800 |
| ple 6 | 8 | 1 | | | | | | |
| Exam- | Ligand | Ligand | 32.5 | 32.9 | 32.5 | 32.0 | 1,600 | 720 |
| ple 7 | 9 | 1 | | | | | | |
| Exam- | Ligand | Ligand | 32.6 | 32.6 | 33.1 | 33.1 | 2,458 | 850 |
| ple 8 | 10 | 1 | | | | | | |
| Exam- | Ligand | Ligand | 32.5 | 32.5 | 33.0 | 32.5 | 2,300 | 716 |
| ple 9 | 11 | 1 | | | | | | |
| Exam- | Ligand | Ligand | 32.8 | 33.0 | 33.5 | 33.2 | 2,300 | 716 |
| ple 10 | 5 | 1 | | | | | | |
| Exam- | Ligand | Ligand | 32.9 | 33.1 | 33.3 | 33.2 | 2,800 | 886 |
| ple 11 | 5 | 1 | | | | | | |

Referring to Table 6, it can be seen that the curable compositions according to one or more embodiments of the present disclosure may have enhanced quantum efficiency and light resistance, regardless of the presence of the solvent.

In the present disclosure, it will be understood that the terms “comprise(s)/comprising,” “include(s)/including,” or “have/has/having” specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, ±20%, ±10%, or ±5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

Although some example embodiments have been described herein, it will be understood by a person having ordinary knowledge in the art that other implementations are also possible and that various modifications, variations and alterations can be made without departing from the spirit and scope of the disclosure. Therefore, it should be understood that these embodiments are given by way of illustration only and are not intended to limit the disclosure. It is further understood that the scope of the present disclosure is defined by the appended claims and equivalents thereof rather than the detailed description provided above, and all modifications and alterations derived from the claims and their equivalents fall within the scope of the present disclosure.

What is claimed is:

1. A curable composition, comprising:
quantum dots containing a first ligand and a second ligand; and
a polymerizable compound,
wherein the first ligand is a compound containing a carboxyl group and a substituted or unsubstituted (meth)acrylate group, and
the second ligand is a compound containing a thiol group and a substituted or unsubstituted C₆ to C₃₀ aryl group.

2. The curable composition as claimed in claim 1, wherein the first ligand is a compound represented by Formula 1:
R¹-L¹-L²-R² Formula 1
wherein, R¹ is a carboxyl group;
L¹ and L² are each independently a single bond, a substituted or unsubstituted C₁ to C₁₀ alkylene group, a substituted or unsubstituted C₂ to C₁₀ alkenylene group, a carbonyl group (—CO—), an ether group (—O—), an ester group (—COO—), or a combination thereof; and
R² is a substituted or unsubstituted (meth)acrylate group or a group represented by Formula 2: 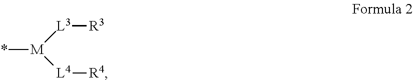
wherein, M is a substituted or unsubstituted C₃ to C₁₀ cycloalkylene group, a trivalent hydrocarbon group, or a combination thereof;
L³ and L⁴ are each independently a single bond, a substituted or unsubstituted C₁ to C₁₀ alkylene group, an ester group, or a combination thereof; and
R³ and R⁴ are each independently a substituted or unsubstituted (meth)acrylate group or a substituted or unsubstituted allyloxy group, provided that at least one of R³ or R⁴ is a substituted or unsubstituted (meth)acrylate group.

3. The curable composition as claimed in claim 2, wherein L¹ and L² are each independently a single bond, a substituted or unsubstituted C₁ to C₁₀ alkylene group, or a combination thereof, and R² is a substituted or unsubstituted (meth)acrylate group.

4. The curable composition as claimed in claim 2, wherein L¹ and L² are each independently a substituted or unsubstituted C₁ to C₁₀ alkylene group, a substituted or unsubstituted C₂ to C₁₀ alkenylene group, or an ester group (—COO—), and M is a trivalent hydrocarbon group.

5. The curable composition as claimed in claim 2, wherein L¹ and L² are each a single bond, and M is a C₄ to C₁₀ cycloalkylene group substituted with a carboxyl group.

6. The curable composition as claimed in claim 1, wherein the first ligand is a compound represented by any one selected from among Formulas 1-1 to 1-3: 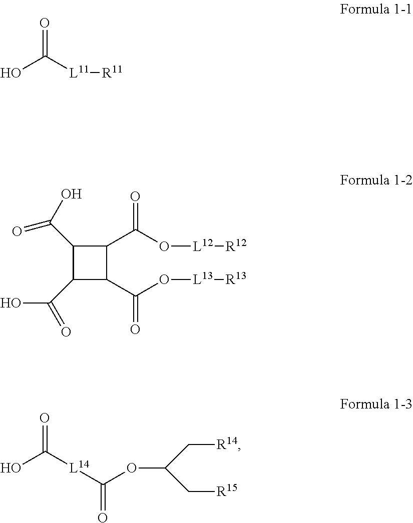
wherein, L¹¹ to L¹⁴ are each independently a substituted or unsubstituted C₁ to C₁₀ alkylene group, a substituted or unsubstituted C₂ to C₁₀ alkenylene group, or a substituted or unsubstituted C₂ to C₁₀ alkyl ether group;
R¹¹ is a substituted or unsubstituted (meth)acrylate group; and
R¹² to R¹⁵ are each independently a substituted or unsubstituted (meth)acrylate group or a substituted or unsubstituted allyloxy group, provided that at least one of R¹² or R¹³ and at least one of R¹⁴ or R¹⁵ are each a substituted or unsubstituted (meth)acrylate group.

7. The curable composition as claimed in claim 1, wherein the second ligand is a compound represented by Formula 3: 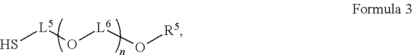
wherein, R⁵ is a substituted or unsubstituted C₆ to C₂₀ aryl group;
L⁵ and L⁶ are each independently a substituted or unsubstituted C₁ to C₁₀ alkylene group; and
n is an integer of 0 to 10.

8. The curable composition as claimed in claim 7, wherein R⁵ is a substituted or unsubstituted benzene group.

9. The curable composition as claimed in claim 1, wherein the first ligand is present in an amount of 20 wt % to 80 wt %, and the second ligand is present in an amount of 80 wt % to 20 wt %, based on a total weight of 100 wt % of the first ligand and the second ligand.

10. The curable composition as claimed in claim 1, wherein the curable composition is a solvent-free curable composition.

11. The curable composition as claimed in claim 10, wherein the solvent-free curable composition comprises: 5 wt % to 60 wt % of the quantum dots; and 40 wt % to 95 wt % of the polymerizable compound based on a total weight of 100 wt % of the solvent-free curable composition.

12. The curable composition as claimed in claim 1, further comprising: a polymerization initiator, a light diffusing agent, a polymerization inhibitor, or a combination thereof.

13. The curable composition as claimed in claim 12, wherein the light diffusing agent comprises barium sulfate, calcium carbonate, titanium dioxide, zirconia, or a combination thereof.

14. The curable composition as claimed in claim 1, wherein the quantum dots comprise a cadmium-free luminescent material.

15. The curable composition as claimed in claim 14, wherein the quantum dots have a core/shell structure of InP/ZnS or a core/first shell/second shell structure of InP/ZnSe/ZnS.

16. The curable composition as claimed in claim 1, wherein the quantum dots comprise: a core comprising Ag, In, Ga, and S; and a shell comprising at least two selected from the group consisting of Ag, Ga, Zn, and S.

17. The curable composition as claimed in claim 1, further comprising: a solvent.

18. The curable composition as claimed in claim 17, comprising: 1 wt % to 40 wt % of the quantum dots; 1 wt % to 20 wt % of the polymerizable compound; and 40 wt % to 80 wt % of the solvent, based on a total weight of 100 wt % of the curable composition.

19. A cured layer produced from the curable composition as claimed in claim 1.

20. A display device comprising the cured layer as claimed in claim 19.
